(19) United States
(12) Patent Application Publication
(10) Pub. No.: US 2015/0015801 A1
(43) Pub. Date: Jan. 15, 2015

(54) TOUCH PANEL AND METHOD OF MANUFACTURING THE SAME

(71) Applicant: Samsung Electro-Mechanics Co., Ltd., Suwon (KR)

(72) Inventors: Jae Hun Kim, Suwon (KR); Sang Su Hong, Suwon (KR); In Hyun Jang, Suwon (KR)

(73) Assignee: Samsung Electro-Mechanics Co., Ltd., Suwon (KR)

(21) Appl. No.: 14/021,754

(22) Filed: Sep. 9, 2013

(30) Foreign Application Priority Data
Sep. 25, 2012 (KR) 10-2012-0106597

(51) Int. Cl. G06F 1/16; G03F 7/30

(52) U.S. Cl. CPC G06F 1/1656; G03F 7/30
USPC 349/12; 430/319

(57) ABSTRACT

Disclosed herein is a touch panel including: a transparent substrate divided into an active region and a non-active area that is a boundary of the active region; and a bezel portion formed in the non-active region of one surface of the transparent substrate, wherein the bezel portion is formed by exposing and developing a silver halide emulsion layer, thereby reducing a step difference of the bezel portion.

### CROSS REFERENCE TO RELATED ED APPLICATION

This application claims the benefit of Korean Patent Application No. 10-2012-0106597, filed on Sep. 25, 2012, entitled “Touch Panel and Method of Manufacturing the Same”, which is hereby incorporated by reference in its entirety into this application.

### BACKGROUND OF THE INVENTION

1. Technical Field

The present invention relates to a touch panel and a method of manufacturing the touch panel.

2. Description of the Related Art

Alongside the growth of computers using digital technology, devices assisting computers have also been developed, and personal computers, portable transmitters and other personal information processors execute processing of text and graphics using a variety of input devices such as a keyboard and a mouse.

While the rapid advancement of the information-based society has been widening the use of computers more and more, there have been occurring the problems of it being difficult to efficiently operate products using only the keyboard and mouse as being currently responsible for the input device function. Thus, the demand for a device that is simple, does not malfunction, and has the capability to easily input information is increasing.

Furthermore, current techniques for input devices exceed the level of fulfilling general functions and thus are progressing towards techniques related to high reliability, durability, innovation, designing and manufacturing. To this end, a touch panel has been developed as an input device capable of inputting information such as text and graphics.

The touch panel is mounted on the display surface of an image display device such as an electronic organizer, a flat panel display including a liquid crystal display (LCD) device, a plasma display panel (PDP), an electroluminescence (El) element or the like, or a cathode ray tube (CRT), so that a user selects the information desired while viewing the image display device.

The touch panel is classifiable as a resistive type, a capacitive type, an electromagnetic type, a surface acoustic wave (SAW) type, and an infrared type. The type of touch panel selected is one that is adapted for an electronic product in consideration of not only signal amplification problems, resolution differences and the degree of difficulty of designing and manufacturing technology but also in light of optical properties, electrical properties, mechanical properties, resistance to the environment, input properties, durability and economic benefits of the touch panel. In current, the resistive type touch panel and the capacitive type touch panel are most prevalently used in a broad range of fields.

Such touch panels include a bezel portion that has a color of black or white to hide an electronic wire or form an ornament pattern in a window glass disposed in the outermost boundary of a general touch panel structure.

An example of a conventional touch panel including the bezel portion may be a touch panel disclosed in Korean Patent No. 10-1074263.

However, the conventional touch panel has a step difference in one surface of the window glass due to the bezel portion formed in the window glass, and has many disconnections of an electronic layer formed in one surface of the window glass due to the step difference caused by the bezel portion during a process of forming the electronic layer.

Therefore, the touch panel needs to consider a structural enhancement method that reduces the step difference due to the bezel portion and solves a disconnection problem of an electrode layer.

### SUMMARY OF THE INVENTION

The present invention has been made in an effort to provide a touch panel that reduces a step difference due to a bezel portion and prevents a disconnection failure of an electronic layer from occurring, and a method of manufacturing the touch panel.

According to a first preferred embodiment of the present invention, there is provided a touch panel including: a transparent substrate divided into an active region and a non-active area that is a boundary of the active region; and a bezel portion formed in the non-active region of one surface of the transparent substrate, wherein the bezel portion is formed by exposing and developing a silver halide emulsion layer.

The bezel portion may include gentle inclined surfaces at both sides in a width direction.

A silver halide included in the silver halide emulsion layer may be an inorganic silver halide.

The touch panel may further include: an overcoat layer formed in the transparent substrate to cover the bezel portion.

The overcoat layer may be formed of an insulation material.

The transparent substrate may be a window glass.

According to a second preferred embodiment of the present invention, there is provided a method of manufacturing a touch panel, the method including: (A) preparing a transparent substrate; (B) applying a silver halide emulsion layer to the transparent substrate; and (C) forming a bezel portion in a non-active region of one surface of the transparent substrate by exposing and developing the silver halide emulsion layer.

The method may further include: forming an overcoat layer in the transparent substrate to cover the silver halide emulsion layer, after step (B).

The overcoat layer may be formed of an insulation material.

In step (C), a surface exposure may be performed on the silver halide emulsion layer using a photomask.

In step (C), a scanning exposure may be performed on the silver halide emulsion layer using a laser beam.

A silver halide included in the silver halide emulsion layer may be an inorganic silver halide.

The transparent substrate may be a window glass.

### BRIEF DESCRIPTION OF THE DRAWINGS

FIG. 1 is plan view of a transparent substrate included in a touch panel according to an embodiment of the present invention;

FIG. 2 is a cross-sectional view of a touch panel according to an embodiment of the present invention;

FIG. 3 is an expanded cross-sectional view of a region A of FIG. 2; and

FIGS. 4, 5, 6, 7A and 7B are cross-sectional views for describing steps of a method of manufacturing a touch panel according to an embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

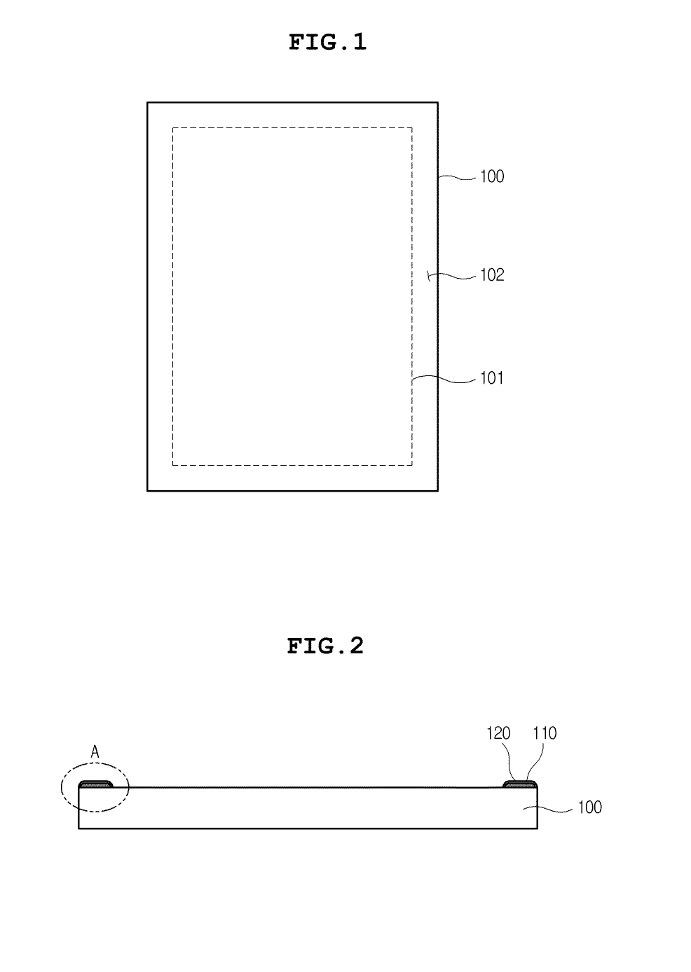

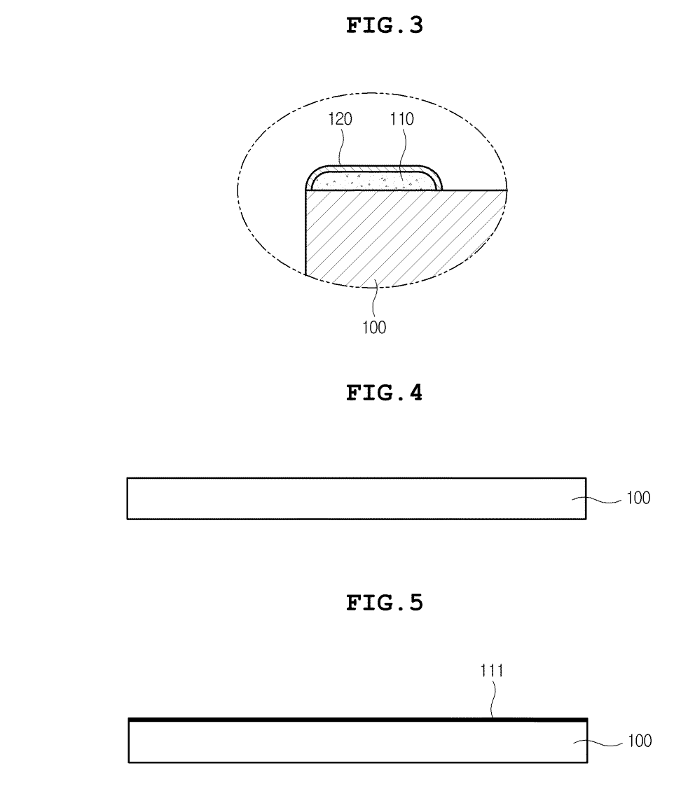

FIG. 1 is plan view of a transparent substrate included in a touch panel according to an embodiment of the present invention. FIG. 2 is a cross-sectional view of a touch panel according to an embodiment of the present invention. FIG. 3 is an expanded cross-sectional view of a region A of FIG. 2.

As shown in FIGS. 1 through 3, the touch panel according to an embodiment of the present invention includes a transparent substrate 100 divided into an active region 101 and a non-active region 102 that is a boundary of the active region 101 and a bezel portion 110 formed in the non-active region 102 of one surface of the transparent substrate 100.

The transparent substrate 100 may act as providing a region in which an electronic layer (not shown) for detecting a touch location is formed. The transparent substrate 100 needs to be equipped with a support force for supporting the electrode layer and transparency by which a user may recognize an image provided by an image display device.

In consideration of the above-described support force and transparency, the transparent substrate 100 may be formed of Polyethylene terephthalate (PET), Polycarbonates (PC), Poly(methyl methacrylate) (PMMA), Polyethylene naphthalate (PEN), Polyether sulfones (PES), Cyclic Olefin Copolymer (COC), Triacetyl Cellulose (TAC) film, Polyvinyl alcohol (PVA) film, Polyimide (PI) film, polystyrene (PS), biaxially oriented polystyrene (BOPS; containing K resin), glass or tempered glass and so on, but the present invention is not limited thereto.

The transparent substrate 100 may be a window glass included in the outermost boundary of the touch panel. In a case where the transparent substrate 100 is the window glass, since the above-described electrode layer is directly formed in the window glass, a process of manufacturing the touch panel may skip a step of attaching the electrode layer to the window glass after forming the electrode layer in the transparent substrate 100, and thus the touch panel may reduce an overall thickness thereof.

Meanwhile, the transparent substrate 100 may be divided into the active region 101 and the non-active region 102 that is a boundary region of the active region 101 as shown in FIG. 1. The active region 101 is a region in which a user carries out a touch function, and is a screen region in which the user visually confirms an operation scene of a device. The non-active region 102 is a region that is hidden by the bezel portion 110, which will be described later, formed in the transparent substrate 100, and not exposed to the outside.

The bezel portion 110 is formed in the non-active region 102 of one surface of the transparent substrate 100 as shown in FIG. 2. The bezel portion 110 may act as hiding a wire (not shown) disposed in a region corresponding to the non-active region 102 of the transparent substrate 100. An ornament pattern such as a logo of a manufacturing company may be formed in the bezel portion 110 as occasions demand.

The bezel portion 110 included in the touch panel of the present embodiment is formed by exposing and developing a silver halide emulsion layer.

The silver halide emulsion layer includes a silver halide and a binder, and may further contain an additive such as a solvent or a dye.

The silver halide may be an inorganic silver halide such as silver halogen and an organic silver halide such as acetic acid.

The binder may use, for example, gellatin Polyvinyl alcohol (PVA), Polyvinylpyrrolidone (PVP), Polysaccaride such as starch, Cellulose and derivative thereof, polyethylene oxide, polyvinylamine, chitosan, poly lysine, polyacrylic acid, poly alginic acid, poly hyaluronic acid, carboxycellulose, etc.

The solvent, although not particularly limited thereto, may use, for example, water, an organic solvent (for example, alcohols such as methanol, ketones such as acetone, amides such as formamide, sulfoxides such as dimethyl sulfoxide, esthers such as ethyl acetate, ethers, etc.), an ionic liquid, and mixed solvents of theses.

Other additives are not particularly limited and may use well-known ones.

The bezel portion 110 formed by exposing and developing the silver halide emulsion layer has a generally dark color as silver particles generated from the exposure and developing of the silver halide emulsion layer have a black color or a dark color close to the black color. Thus, the silver halide emulsion layer may serve as a color ink layer formed as a bezel portion of the conventional touch panel.

The silver halide emulsion layer is coated on one surface of the transparent substrate 100 and then exposed and developed so that the bezel portion 110 formed through the above process has gentle inclination surfaces at both sides thereof in a width direction as shown in FIG. 3.

The above-described electrode layer may be formed in the active region 101 of one surface of the transparent substrate 100 of the touch panel according to the present embodiment. The electrode layer may be formed by coating and patterning a metallic material in a whole one surface of the transparent substrate 100 through a deposition or plating process, for example, in a mesh pattern.

In this regard, since the bezel portion 110 has gentle inclination surfaces at both sides thereof in the width direction, the touch panel according to the present embodiment has an excellent adhesion force of the electrode layer coated in the whole one surface of the transparent substrate 100. Thus, a disconnection failure of a patterned electrode layer does not occur in the touch panel according to the present embodiment.

Also, the transparent substrate 100 of the touch panel according to the present embodiment may be adhered to an additional transparent substrate in which the electrode layer is formed by means of a bonding layer (not shown). In this regard, the bonding layer and the transparent substrate 100 may not be spaced apart from each other and may be bonded to each other in the bezel portion 110 due to the inclined surfaces of both sides of the bezel portion 110 in the width direction. Thus, there is no failure that the additional transparent substrate adhered by means of the bonding layer is exfoliated from the transparent substrate 100 of the touch panel according to the present embodiment.

The touch panel according to the present embodiment may further include an overcoat layer 120, in addition to the above-described construction.

The overcoat layer 120 is formed on the transparent substrate 100 to cover the bezel portion 110 and may serve to protect the bezel portion 110 from an external environment.

The overcoat layer 120 may be present in a manner of covering the bezel portion 110 only as shown in FIG. 2. Alternatively, the overcoat layer 120 may be present in a manner of covering the entire surface of the transparent substrate 100 including the bezel portion 110 (see FIG. 7B).

As the overcoat layer 120 is stacked and formed in the bezel portion 110, gentle inclination surfaces of the overcoat layer 120 at both sides thereof in a width direction correspond to the gentle inclination surfaces of the bezel portion 110 at both sides thereof in the width direction. Thus, in a case where the touch panel of the present embodiment further includes the overcoat layer 120, the above-described adhesion force of the electrode layer or bonding force of the bonding layer is excellent.

Meanwhile, the bezel portion 110 formed by exposing and developing the silver halide emulsion layer includes metallic silver, and thus the bezel portion 110 may be electrical conductivity. In this case, as described above, in a case where the electrode layer is directly formed in one surface of the transparent substrate 100, and in a case where electrode wires (not shown) are disposed in a location corresponding to the non-active region 102 of the transparent substrate 100, the bezel portion 110 and the electrode layer or the bezel portion 110 and the electrode wires are electrically connected to each other, which may cause a problem that a disconnection occurs in the electrode layer or between the electrode wires.

Therefore, the overcoat layer 120 may be formed of an insulating material so as to prevent such disconnection from occurring. The overcoat layer 120 may include, for example, acryl or polyimide as an organic resin insulation material, or may include, for example, silicon oxide, silicon nitride, nitrogen containing silicon oxide, oxide containing silicon nitride, etc. as an inorganic resin insulation material.

A method of manufacturing the touch panel according to the present embodiment will now be described with reference to the accompanying drawings.

FIGS. 4 through 7 are cross-sectional views for describing steps of a method of manufacturing a touch panel according to an embodiment of the present invention.

The method of manufacturing the touch panel according to the present embodiment includes (A) preparing the transparent substrate 100, (B) applying a silver halide emulsion layer 111 to the transparent substrate 100, and (C) forming the bezel portion 110 in the non-active region 102 of one surface of the transparent substrate 100 by exposing and developing the silver halide emulsion layer 111.

Step (A) is a step of preparing the transparent substrate 100 as shown in FIG. 4.

The transparent substrate 100 may be formed of the above-described transparent materials. The transparent substrate 100 may be a window glass included in the outermost boundary of the touch panel. The transparent substrate 100 may be divided into the active region 101 and the non-active region 102 (see FIG. 1).

Step (B) is a step of applying the silver halide emulsion layer 111 to the transparent substrate 100 as shown in FIG. 5.

The silver halide emulsion layer 111 includes a silver halide and a binder, and may further contain an additive such as a solvent or a dye. The silver halide may be an inorganic silver halide such as silver halogen and an organic silver halide such as acetic acid.

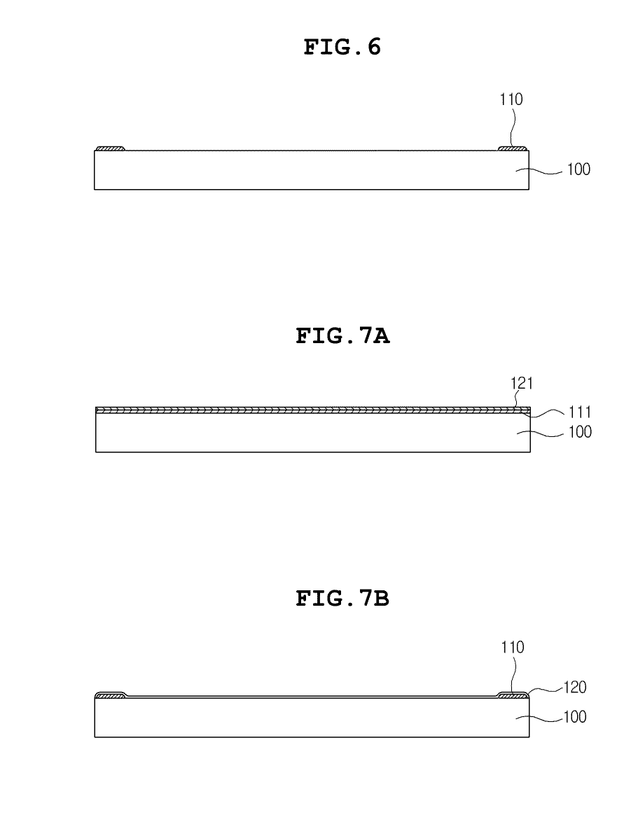

Step (C) is a step of forming the bezel portion 110 by exposing and developing the silver halide emulsion layer 111 as shown in FIG. 6.

A specific method of exposing the silver halide emulsion layer 111 may use a method of a surface exposure using a photomask or a scanning exposure method by a laser beam. Alternatively, the method may use a variety of methods of refractive exposure using a lens, reflective exposure using a reflective mirror, contact exposure, proximity exposure, reduced projection exposure, reflective projection exposure, etc.

A developing process is additionally performed after the silver halide emulsion layer 111 is exposed as described above. The developing process may use a general developing technology used in a silver halide photo film or a photographic paper, a print plating film, a photomask emulsion mask, etc.

The bezel portion 110 formed by exposing and developing the silver halide emulsion layer 111 is formed in the non-active region 102 of one surface of the transparent substrate 100.

Meanwhile, the method of manufacturing the touch panel according to the present embodiment may further include forming the overcoat layer 120 (see FIG. 2) in the transparent substrate 100 to cover the silver halide emulsion layer 111 after step (B).

The overcoat layer 120 may serve to protect the bezel portion 110 from an external environment. The overcoat layer 120 may be formed of an insulation material to insulate the bezel portion 110 from the outside.

This step may be a step of applying an insulation material 121 to the transparent substrate 100 in a state where the silver halide emulsion layer 111 is applied to the transparent substrate 100 (see FIG. 5) in such a way that the insulation material 121 is stacked on the silver halide emulsion layer 111 as shown in FIG. 7A. Thereafter, if step (C) is performed, as shown in FIG. 7B, the silver halide emulsion layer 111 covered by the insulation material 121 is removed during a developing process or a fixing process that may be performed after the developing process, and thus the bezel portion 110 may be formed in the non-active region 102 of the transparent substrate 100. After step (C), an etching process may be further performed on the overcoat layer 120, or the overcoat layer 120 may be present in a manner of covering the bezel portion 110 only through the etching process (see FIG. 2).

According to the present invention, gentle inclined surfaces are formed in both sides of a bezel portion in a width direction, thereby reducing a step difference due to the bezel portion. Accordingly, a touch panel according to the present invention may further enhance an adhesion force of an electronic layer formed in a transparent substrate or a bonding force of a bonding layer formed in the transparent substrate, and prevent a problem such as a disconnection of an electrode or an exfoliation of the bonding layer from occurring.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch panel comprising:
a transparent substrate divided into an active region and a non-active area that is a boundary of the active region; and
a bezel portion formed in the non-active region of one surface of the transparent substrate,
wherein the bezel portion is formed by exposing and developing a silver halide emulsion layer.

2. The touch panel as set forth in claim 1, wherein the bezel portion includes gentle inclined surfaces at both sides in a width direction.

3. The touch panel as set forth in claim 1, wherein a silver halide included in the silver halide emulsion layer is an inorganic silver halide.

4. The touch panel as set forth in claim 1, further comprising: an overcoat layer formed in the transparent substrate to cover the bezel portion.

5. The touch panel as set forth in claim 4, wherein the overcoat layer is formed of an insulation material.

6. The touch panel as set forth in claim 1, wherein the transparent substrate is a window glass.

7. A method of manufacturing a touch panel, the method comprising:
(A) preparing a transparent substrate;
(B) applying a silver halide emulsion layer to the transparent substrate; and
(C) forming a bezel portion in a non-active region of one surface of the transparent substrate by exposing and developing the silver halide emulsion layer.

8. The method as set forth in claim 7, further comprising: forming an overcoat layer in the transparent substrate to cover the silver halide emulsion layer, after step (B).

9. The method as set forth in claim 8, wherein the overcoat layer is formed of an insulation material.

10. The method as set forth in claim 7, wherein, in step (C), a surface exposure is performed on the silver halide emulsion layer using a photomask.

11. The method as set forth in claim 7, wherein, in step (C), a scanning exposure is performed on the silver halide emulsion layer using a laser beam.

12. The method as set forth in claim 7, wherein a silver halide included in the silver halide emulsion layer is an inorganic silver halide.

13. The method as set forth in claim 7, wherein the transparent substrate is a window glass.
